(19) United States
(12) Patent Application Publication
(10) Pub. No.: US 2024/0210546 A1
(43) Pub. Date: Jun. 27, 2024

(54) ULTRASONIC SENSOR

(71) Applicant: Murata Manufacturing Co., Ltd., Nagaokakyo-shi, Kyoto-fu (JP)

(72) Inventor: Hirokazu NAKANISHI, Nagaokakyo-shi (JP)

(21) Appl. No.: 18/596,866

(22) Filed: Mar. 6, 2024

Related U.S. Application Data
(63) Continuation of application No. PCT/JP2022/032398, filed on Aug. 29, 2022.

(30) Foreign Application Priority Data
Sep. 29, 2021 (JP) 2021-158580

(51) Int. Cl. G01S 7/521; B06B 1/06

(52) U.S. Cl. CPC G01S 7/521; B06B 1/0655

(57) ABSTRACT

An ultrasonic sensor includes a vibration body including a cylindrical portion and a bottom portion that closes one end of the cylindrical portion, a piezoelectric element fixed to an inner surface of the bottom portion of the vibration body, a housing including a portion storing the vibration body, and an elastic portion interposed between the vibration body and the housing portion. The elastic portion includes a front and rear symmetrical shape and includes a closed-cell structure.

### CROSS REFERENCE TO RELATED APPLICATIONS

This application claims the benefit of priority to Japanese Patent Application No. 2021-158580 filed on Sep. 29, 2021 and is a Continuation Application of PCT Application No. PCT/JP2022/032398 filed on Aug. 29, 2022. The entire contents of each application are hereby incorporated herein by reference.

### BACKGROUND OF THE INVENTION

### 1. Field of the Invention

The present invention relates to ultrasonic sensors.

### 2. Description of the Related Art

An example of an ultrasonic sensor is described in Japanese Patent No. 4438667. The ultrasonic sensor described in Japanese Patent No. 4,438,667 includes an ultrasonic transducer. The ultrasonic transducer includes a housing having a cylindrical shape with a bottom, a piezoelectric element fixed to a bottom portion of the housing, and a base fixed to an opening of the housing with a spacer interposed therebetween. The spacer is made of an elastic body. The housing includes the bottom portion and a cylindrical portion. The spacer is an elastic body that prevents unnecessary vibration, caused by vibration of the bottom portion, generated in the cylindrical portion from being transferred to the base. Such an ultrasonic transducer is covered with a cylindrical elastic body, and a foamed elastic body is disposed on a lower side of the base as an elastic body that suppresses vibration.

### SUMMARY OF THE INVENTION

The spacer of Japanese Patent No. 4,438,667 has a rib shape, and an outer surface of the rib shape is exposed to an outer peripheral surface of the ultrasonic transducer so as to hinder vibration transfer. Since the spacer has a front and rear asymmetrical shape, attention is required during assembly so as not to make a mistake in arranging the front and the rear.

Japanese Patent No. 4,438,667 describes that the spacer is made of, for example, silicon rubber. However, such a spacer has a large specific gravity, and does not have a sufficient effect of hindering vibration transfer. When such a spacer is in contact with the housing, fluctuation in the frequency of unnecessary vibration and variation in the product characteristics may be caused.

Therefore, example embodiments of the present invention provide ultrasonic sensors that achieve easier assembly and reduce or prevent unnecessary vibration transfer as much as possible.

An ultrasonic sensor according to an example embodiment of the present invention includes a vibration body including a cylindrical portion and a bottom portion that closes one end of the cylindrical portion, a piezoelectric element fixed to an inner surface of the bottom portion of the vibration body, a first housing portion of a housing storing the vibration body, and a first elastic member interposed between the vibration body and the first housing portion. The first elastic member includes a front and rear symmetrical shape and includes a closed-cell structure.

According to example embodiments of the present invention, since the first elastic member that is interposed between the vibration body and the first housing portion includes a front and rear symmetrical shape and includes a closed-cell structure, ultrasonic sensors achieve easier assembly and reduce or prevent unnecessary vibration transfer as much as possible can be achieved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a first perspective view of an ultrasonic sensor according to a first example embodiment of the present invention.

FIG. 2 is an exploded view of the ultrasonic sensor according to the first example embodiment of the present invention.

FIG. 3 is an exploded view related to a vibration body included in the ultrasonic sensor according to the first example embodiment of the present invention.

FIG. 4 is a second perspective view of the ultrasonic sensor according to the first example embodiment of the present invention.

FIG. 5 is a cross-sectional view taken along an arrow line V-V in FIG. 4.

FIG. 6 is a cross-sectional view taken along an arrow line VI-VI in FIG. 4.

FIG. 7 is a cross-sectional view of a portion illustrated in FIG. 5 in a state in which a first filling member and a second filling member are removed.

FIG. 8 is a cross-sectional view of a portion illustrated in FIG. 6 in a state in which the first filling member and the second filling member are removed.

FIG. 9 is an exploded view of some components of a component group illustrated in FIG. 2 when viewed in a different direction.

FIG. 10 is an exploded view of a component group illustrated in FIG. 9 in a state of being assembled halfway.

FIG. 11 is a perspective view of a state in which the vibration body, a second elastic member, and a second housing portion included in the ultrasonic sensor according to the first example embodiment of the present invention are assembled.

FIG. 12 is a perspective view of a state in which a first elastic member 4 is assembled in a portion illustrated in FIG. 11.

FIG. 13 is a first explanatory diagram for illustrating advantages of the first elastic member including a closed-cell structure.

FIG. 14 is a second explanatory diagram for illustrating advantages of the first elastic member including a closed-cell structure.

FIG. 15 is a graph indicating magnitude of a reaction force generated around an elastic member with respect to a pushed-in amount given to the elastic member.

### DETAILED DESCRIPTION OF THE EXAMPLE EMBODIMENTS

The dimensional ratios illustrated in the drawings do not always faithfully represent the actual dimensional ratios, and the dimensional ratios may be exaggerated for convenience of description. In the following description, when referring to the concept of above or below, it does not necessarily mean absolute above or below, but may mean relative above or below in the illustrated positions.

### First Example Embodiment

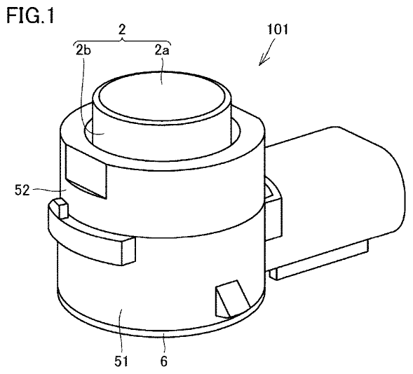

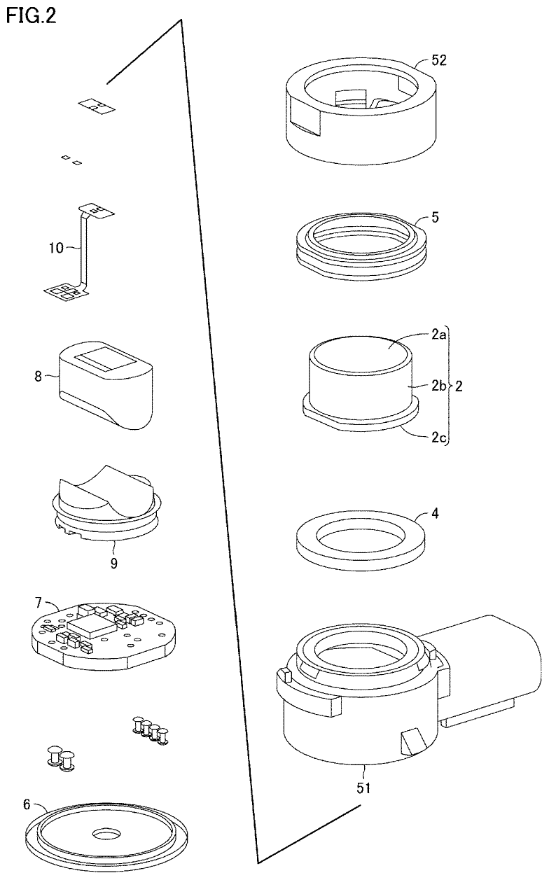

With reference to FIGS. 1 to 12, an ultrasonic sensor according to a first example embodiment based on the present invention will be described. FIG. 1 illustrates an ultrasonic sensor 101 according to the present example embodiment. FIG. 2 illustrates an exploded view of the ultrasonic sensor 101. The ultrasonic sensor 101 includes a rear cover 6, a wiring board assembly 7, a first filling member 8, a second filling member 9, wiring 10, a first housing portion 51, a first elastic member 4, a vibration body 2, a second elastic member 5, and a second housing portion 52. The first elastic member 4 includes a closed-cell structure. The vibration body 2 has a cylindrical or substantially cylindrical shape with a bottom. The vibration body 2 is made of, for example, metal. Here, the metal is, for example, aluminum. The vibration body 2 includes a bottom portion 2a, a cylindrical portion 2b, and a flange portion 2c. The first housing portion 51 and the second housing portion 52 are made of, for example, resin. The material of the first housing portion 51 and the second housing portion 52 may be the same kind. The rear cover 6 may be made of, for example, resin. The first filling member 8 is made of, for example, foamed silicone. The second filling member 9 is, for example, a silicone member disposed by potting processing. The second elastic member 5 is made of, for example, rubber.

As illustrated in FIG. 3, a piezoelectric element 1 is disposed inside the vibration body 2. The piezoelectric element 1 is attached to an inner surface of the bottom portion 2a with an adhesive sheet 3 interposed therebetween. The adhesive sheet 3 may be a double-sided tape.

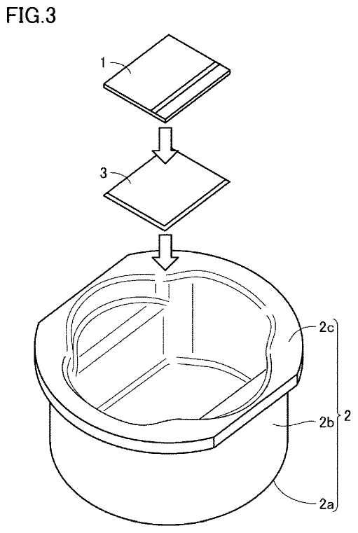

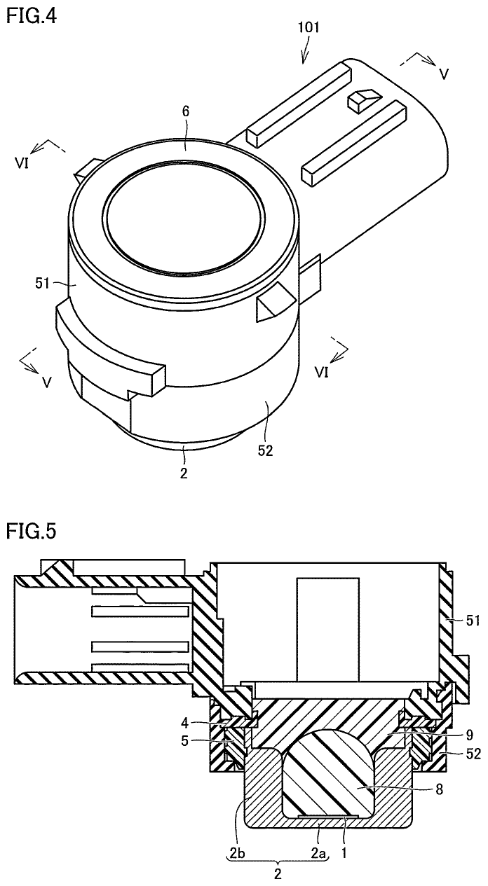

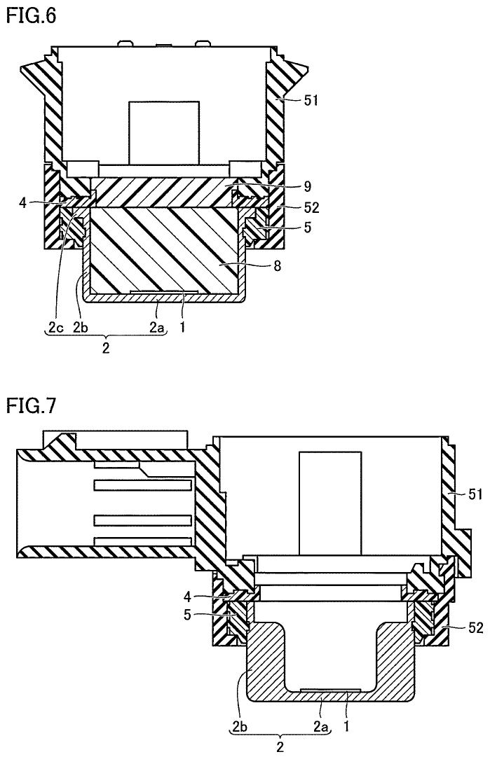

FIG. 4 illustrates the ultrasonic sensor 101 in an orientation in which the rear cover 6 faces up. The orientation illustrated in FIG. 4 corresponds to a state in which the ultrasonic sensor 101 illustrated in FIG. 1 is inverted in an up-and-down direction. FIG. 5 is a cross-sectional view taken along an arrow line V-V in FIG. 4. FIG. 6 is a cross-sectional view taken along an arrow line VI-VI in FIG. 4. In FIGS. 5 and 6, the rear cover 6, the wiring board assembly 7, the wiring 10, the adhesive sheet 3, and the like are not illustrated.

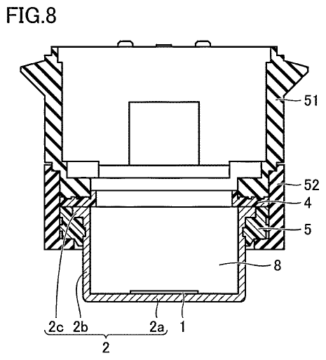

The first elastic member 4 is interposed between the vibration body 2 and the first housing portion 51. The first filling member 8 is disposed inside the vibration body 2 so as to be in contact with the piezoelectric element 1 and the bottom portion 2a. Moreover, the second filling member 9 is disposed so as to cover the first filling member 8. A portion of the second filling member 9 protrudes to the outside from the internal space of the vibration body 2. The first elastic member 4 has an annular shape. That is, the first elastic member 4 has an opening. The second filling member 9 penetrates the opening of the first elastic member 4. FIG. 7 illustrates a portion illustrated in FIG. 5 in a state in which the first filling member 8 and the second filling member 9 are removed. FIG. 8 illustrates a portion illustrated in FIG. 6 in a state in which the first filling member 8 and the second filling member 9 are removed.

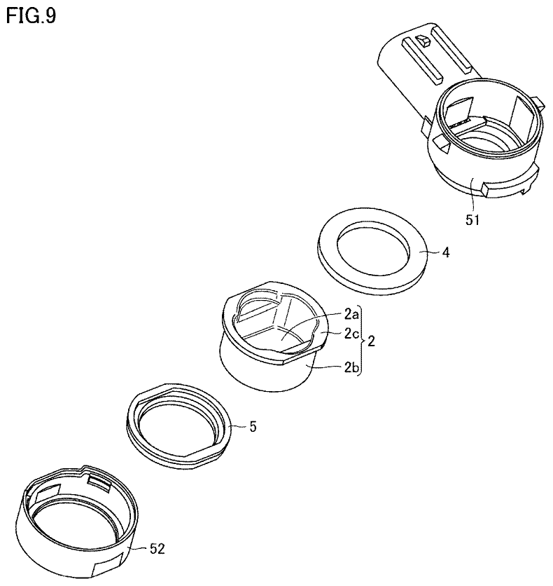

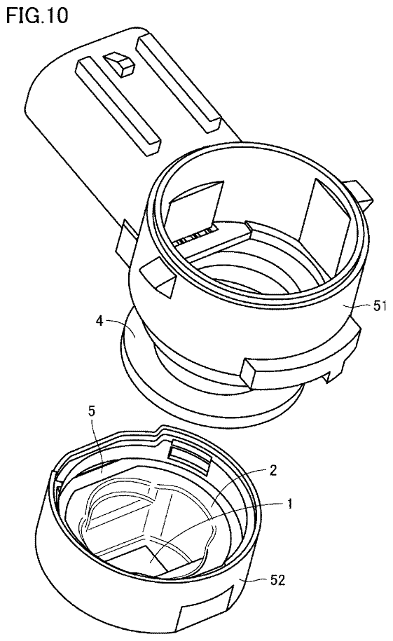

FIG. 9 is an exploded view of some components of a component group illustrated in FIG. 2 when viewed in a different direction. FIG. 9 illustrates the first housing portion 51, the first elastic member 4, the vibration body 2, the second elastic member 5, and the second housing portion 52. FIG. 10 illustrates a state in which the above-described components are assembled halfway. FIG. 10 also illustrates the piezoelectric element 1 attached to the inner surface of the vibration body 2. FIG. 11 illustrates a state in which the vibration body 2, the second elastic member 5, and the second housing portion 52 are assembled. FIG. 12 illustrates a state in which the first elastic member 4 is further assembled in a portion illustrated in FIG. 11.

The configuration of the ultrasonic sensor 101 can be expressed as described below, for example. The ultrasonic sensor 101 includes the vibration body 2 including the cylindrical portion 2b and the bottom portion 2a that closes one end of the cylindrical portion 2b, the piezoelectric element 1 fixed to an inner surface of the bottom portion 2a of the vibration body 2, the first housing portion 51 defining at least a portion of a housing storing the vibration body 2, and the first elastic member 4 interposed between the vibration body 2 and the first housing portion 51. The first elastic member 4 includes a front and rear symmetrical shape and includes a closed-cell structure.

In the present example embodiment, since the ultrasonic sensor 101 includes the first elastic member 4 that is interposed between the vibration body 2 and the first housing portion 51, and the first elastic member 4 includes a closed-cell structure, vibration transfer from the vibration body 2 to the first housing portion 51 can be more effectively hindered. That is, unnecessary vibration transfer can be reduced or prevented as much as possible. In addition, since the first elastic member 4 has a front and rear symmetrical shape, assembly operation can be performed without paying attention to distinction between the front and the rear. Therefore, the assembly operation is facilitated.

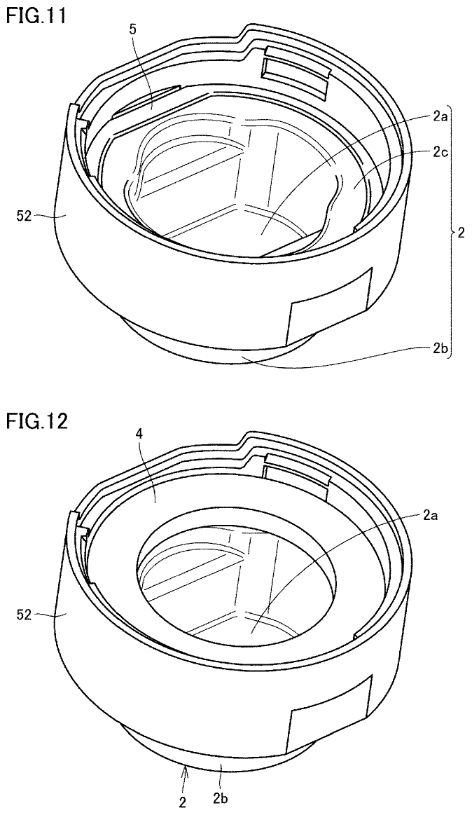

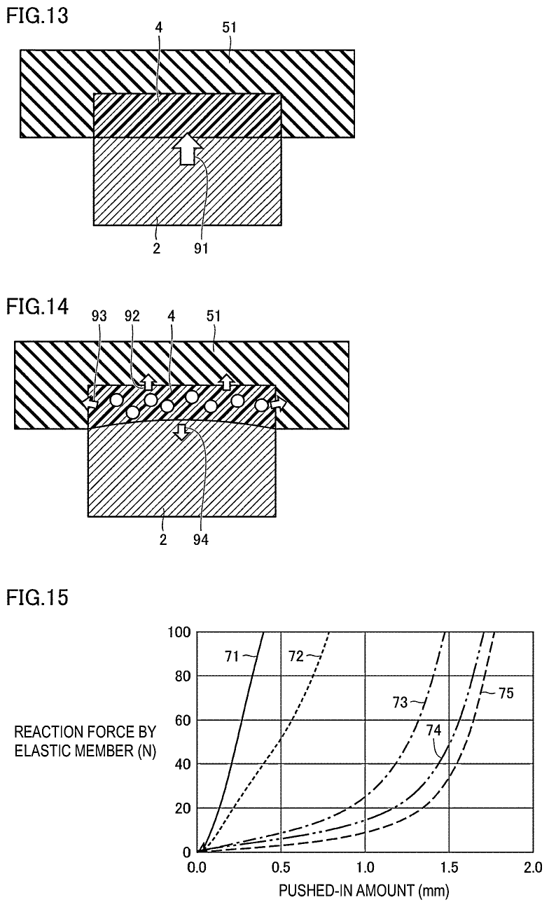

With reference to FIGS. 13 and 14, advantages of the first elastic member 4 including a closed-cell structure will be described. In FIGS. 13 and 14, for convenience of description, the structure is schematically illustrated. As illustrated in FIG. 13, the first elastic member 4 is interposed between the first housing portion 51 and the vibration body 2, and it is assumed that when the vibration body 2 vibrates, an upper surface of the vibration body 2 is displaced upward as indicated by an arrow 91. As a result, a lower surface of the first elastic member 4 is pushed and is displaced so as to enter the inside of the first elastic member 4, thereby acting in a direction so as to reduce the volume of the first elastic member 4.

If the first elastic member 4 is made of rubber, the first elastic member 4 has a fixed Poisson ratio, and thus when the lower surface of the first elastic member 4 is pushed in, an upper surface and an outer peripheral surface of the first elastic member 4 is pushed out from the original surfaces by the amount corresponding to the volume pushed in. As a result, the first housing portion 51 is pushed and displaced. When such displacement is repeated, vibration is transferred to the first housing portion 51.

However, when the first elastic member 4 includes a closed-cell structure, each of the closed cells inside the first elastic member 4 can be compressed and contracted. Therefore, the imposed volume change is absorbed to some extent by the closed cells. As a result, as illustrated by arrows 92 and 93 in FIG. 14, the pushing force of the upper surface and the outer peripheral surface of the first elastic member 4 from the original surfaces toward outside is decreased. Therefore, the amount of displacement of the first housing portion 51 being pushed is also reduced. As a result, the degree of vibration transfer to the first housing portion 51 can be reduced.

FIG. 15 is a graph indicating the magnitude of a reaction force generated around an elastic member with respect to a pushed-in amount given to the elastic member. In FIG. 15, a curved line 71 indicates a case in which rubber having a hardness of 50 is used as the elastic member. A curved line 72 indicates a case in which rubber having a hardness of 30 is used as the elastic member. A curved line 73 indicates a case in which sponge having a hardness of 30 is used as the elastic member. A curved line 74 indicates a case in which sponge having a hardness of 20 is used as the elastic member. A curved line 75 indicates a case in which a sponge having a hardness of about 15 is used as the elastic member, for example. The hardness of rubber is measured by a type A durometer (Asker A type) conforming to JIS K6253-3. The hardness of the sponge is measured by a type E durometer (Asker C type) conforming to JIS K6253-3. JIS K6253-3 of the JIS standard corresponds to ISO 48-4 of the ISO standard. The curved lines 71 and 72 correspond to a case in which a member not including a closed-cell structure is used, and the curved lines 73, 74, and 75 correspond to a case in which a member including a closed-cell structure is used.

As illustrated in FIG. 15, compared to the curved lines 71 and 72, reaction forces of the curved lines 73, 74, and 75 tend to be reduced to be small even with respect to the same pushed-in amount. The reaction forces being reduced to be small means that unnecessary vibration transfer is easily reduced or prevented.

Note that a member including closed cells does not easily allow water or the like to pass therethrough, compared to a member including open cells, and thus has high waterproof capability. When the member includes open cells, since air passes through the member, pickup by vacuum suction is difficult to perform, but when the member includes closed cells, since air does not pass through the member, pickup by vacuum suction is easily performed.

In addition, when the first filling member 8 and the second filling member 9 are formed, in a case in which forming is performed through filling with a liquid material, the first elastic member 4 is preferably a member including closed cells so that entry of the liquid material into the first elastic member 4 can be avoided.

The inventor discovered a state of reverberation in a case in which the Asker hardness, which is a hardness of sponge, is about 10, and in a case in which the Asker hardness is about 30, for example. That is, the piezoelectric element 1 was driven and vibrated the vibration body 2 only for a fixed time, and the vibration remaining when the piezoelectric element 1 is stopped thereafter, that is, the reverberation, was observed. As a result, the inventor confirmed that the reverberation is reduced to be small in the case in which the Asker hardness is about 10, compared to the case in which the Asker hardness is about 30, for example.

In addition, the inventor performed an experiment to measure a reverberation time at a low temperature related to the respective first elastic members 4 having a hardness of about 10, about 15, and about 20, for example. It was discovered that although the elastic member is hardened at a low temperature, the state of a reaction force being small can be maintained, and the function of hindering vibration transfer is excellent.

The inventor performed an experiment by changing the thickness of the first elastic member 4 to several different thicknesses. Assuming that there is a gap of about 0.85 mm, the inventor disposed the first elastic member 4 in the gap in a compressed state and measured various characteristics of a sensor, but little influence was observed in the characteristics by the difference in thickness. Therefore, a rough design can be made, that is, design tolerance can be eased. Since the first elastic member 4 including closed cells is lightweight compared to rubber or the like, the degree of influence on a frequency is very small.

Note that as illustrated in the present example embodiment, the vibration body 2 preferably includes the flange portion 2c, and the first elastic member 4 is preferably in contact with the flange portion 2c. By adopting this configuration, the first elastic member 4 can stably support the vibration body 2. The degree of transfer of unnecessary vibration to other members from the vibration body 2 can be reduced by the first elastic member 4.

As illustrated in the present example embodiment, the first elastic member 4 is preferably a structure having an annular shape with a uniform or substantially uniform thickness. By adopting this configuration, the vibration body 2 can be easily uniformly supported. The first elastic member 4 may be formed, for example, through punching of a plate material with a uniform or substantially uniform thickness.

The first elastic member 4 preferably includes silicone, modified silicone, or urethane. By adopting this configuration, unnecessary vibration transfer can be effectively reduced or prevented. The first elastic member 4 is formed through performing of a foam treatment in which a closed-cell structure can be formed in a material that satisfies the above-described conditions.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An ultrasonic sensor comprising:
a vibration body including a cylindrical or substantially cylindrical portion and a bottom portion that closes one end of the cylindrical or substantially cylindrical portion;
a piezoelectric element fixed to an inner surface of the bottom portion of the vibration body;
a first housing portion of a housing storing the vibration body; and
a first elastic member interposed between the vibration body and the first housing portion; wherein
the first elastic member includes a front and rear symmetrical shape and includes a closed-cell structure.

2. The ultrasonic sensor according to claim 1, wherein
the vibration body includes a flange portion; and
the first elastic member is in contact with the flange portion.

3. The ultrasonic sensor according to claim 1, wherein the first elastic member has an annular shape with a uniform or substantially uniform thickness.

4. The ultrasonic sensor according to claim 1, wherein the first elastic member includes at least one of silicone, modified silicone, or urethane.

5. The ultrasonic sensor according to claim 1, further comprising a second elastic member and a second housing portion.

6. The ultrasonic sensor according to claim 5, wherein the first housing portion and the second housing portion are made of resin.

7. The ultrasonic sensor according to claim 5, wherein the first housing portion and the second housing portion are made of a same material.

8. The ultrasonic sensor according to claim 5, wherein the second elastic member is made of rubber.

9. The ultrasonic sensor according to claim 1, wherein the vibration body is made of metal.

10. The ultrasonic sensor according to claim 1, wherein the vibration body is made of aluminum.

11. The ultrasonic sensor according to claim 1, further comprising a rear cover.

12. The ultrasonic sensor according to claim 1, further comprising a wiring board assembly.

13. The ultrasonic sensor according to claim 1, further comprising a first filling material disposed inside the vibration body and a second filling material disposed on the first filling material.

14. The ultrasonic sensor according to claim 13, wherein the first filling material is foamed silicone and the second filling material is potted silicone.

15. The ultrasonic sensor according to claim 13, wherein the first filling material penetrates an opening in the first elastic member.

16. The ultrasonic sensor according to claim 1, further comprising an adhesive sheet attaching the piezoelectric element to the bottom portion.

17. The ultrasonic sensor according to claim 16, wherein the adhesive sheet includes a double-sided tape.

18. The ultrasonic sensor according to claim 1, wherein the closed-cell structure of the first elastic member is made of a foamed material.
